(19) United States
(12) Patent Application Publication
(10) Pub. No.: US 2022/0037522 A1
(43) Pub. Date: Feb. 3, 2022

(54) TRENCH MOSFET AND METHOD FOR MANUFACTURING THE SAME

(71) Applicant: Silergy Semiconductor Technology (Hangzhou) LTD, Hangzhou (CN)

(72) Inventors: Jiakun Wang, Hangzhou (CN); Bing Wu, Hangzhou (CN)

(21) Appl. No.: 17/370,124

(22) Filed: Jul. 8, 2021

(30) Foreign Application Priority Data
Jul. 29, 2020 (CN) 202010743025.6

(51) Int. Cl. H01L 29/78; H01L 29/40; H01L 29/66

(52) U.S. Cl. CPC H01L 29/7813; H01L 29/66734; H01L 29/407

(57) ABSTRACT

A trench MOSFET can include: a semiconductor base having a first doping type; a trench extending from an upper surface of the semiconductor base to internal portion of the semiconductor base; an insulating layer and an electrode conductor located in the trench; a body region having a second doping type and extending from the upper surface of the semiconductor base to the inside thereof and adjacent to the trench; a source region having the first doping type and located in the body region, a first barrier layer located on the electrode conductor and the semiconductor base; and a contact hole in the semiconductor base on both sides of the first barrier layer, where the contact hole is formed by etching process using the first barrier layer as a mask.

### RELATED APPLICATIONS

This application claims the benefit of Chinese Patent Application No. 202010743025.6, filed on Jul. 29, 2020, which is incorporated herein by reference in its entirety.

### FIELD OF THE INVENTION

The present invention generally relates to semiconductor technology, and more particularly to trench MOSFETs and methods of making trench MOSFETs.

### BACKGROUND

A switched-mode power supply (SMPS), or a “switching” power supply, can include a power stage circuit and a control circuit. When there is an input voltage, the control circuit can consider internal parameters and external load changes, and may regulate the on/off times of the switch system in the power stage circuit. Switching power supplies have a wide variety of applications in modern electronics. For example, switching power supplies may include power switches (e.g., trench MOSFETs), and can be used to drive light-emitting diode (LED) loads.

### BRIEF DESCRIPTION OF THE DRAWINGS

FIG. 1 is cross-sectional view of an example trench MOSFET, in accordance with embodiments of the present invention.

FIGS. 2A-2H are cross-sectional view of formation steps of an example method of making a trench MOSFET, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

Metal-oxide-semiconductor field-effect transistors (MOSFETs) have been widely used as power semiconductor devices, such as switches in power converters. In the traditional approach to making trench MOSFET devices, the body region, source region, and body contact region are formed first, then the interlayer dielectric layer on the semiconductor substrate is formed, and finally the interlayer dielectric layer and part of the semiconductor substrate are etched to form a conductive channel. In one example, in the process of ion implantation to form the body region, the source region, and the body contact region, there may be a problem of alignment deviation, which can affect process reliability. In addition, in the process of forming the conductive channel, an additional mask may be required, which can increase the complexity of the process.

Unless the context clearly indicates otherwise, each part of the semiconductor device can be made of material(s) well known to one skilled person in the art. The semiconductor material can include for example group III-V semiconductor, such as GaAs, InP, GaN, and SiC, and group IV semiconductor, such as Si and Ge. A gate conductor may be made of any conductive material, such as metal, doped polysilicon, and a stack of metal and doped polysilicon, among others. For example, the gate conductor may be made of one selected from a group consisting of TaC, TiN, TaSiN, HfSiN, TiSiN, TiCN, TaAlC, TiAlN, TaN, PtSix, Ni₃Si, Pt, Ru, W, and their combinations. A gate dielectric may be made of SiO₂ or any material having dielectric constant larger than that of SiO2. For example, the gate dielectric may be made of one selected from a group consisting of oxides, nitrides, oxynitrides, silicates, aluminates, and titanates. Moreover, the gate dielectric can be made of those developed in the future, besides the above known materials.

In particular embodiments, a trench MOSFET can include: a semiconductor base having a first doping type; a trench extending from an upper surface of the semiconductor base to internal portion of the semiconductor base; an insulating layer and an electrode conductor located in the trench; a body region having a second doping type and extending from the upper surface of the semiconductor base to the inside thereof and adjacent to the trench; a source region having the first doping type and located in the body region, a first barrier layer located on the electrode conductor and the semiconductor base; and a contact hole in the semiconductor base on both sides of the first barrier layer, where the contact hole is formed by etching process using the first barrier layer as a mask.

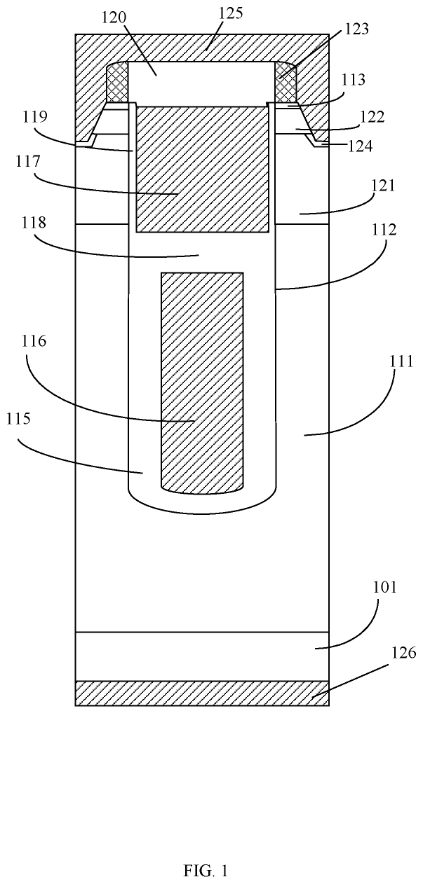

Referring now to FIG. 1, shown is cross-sectional view of an example trench MOSFET, in accordance with embodiments of the present invention. In this particular example, the semiconductor base can include semiconductor substrate 101, and epitaxial semiconductor layer 111 located on semiconductor substrate 101. Semiconductor substrate 101 can include silicon, and may be of a first doping type. The “first” doping type is one of N-type and P-type, and a “second” doping type is the other one of N-type and P-type. In order to form an N-type epitaxial semiconductor layer or region, an N-type dopant (e.g., P, As) can be doped in the epitaxial semiconductor layer and region. In order to form a P-type epitaxial semiconductor layer or region, a P-type dopant (e.g., B) can be doped in the epitaxial semiconductor layer and region. For example, semiconductor substrate 101 is an N-type doped.

Epitaxial semiconductor layer 111 of the first doping type may be on a surface of semiconductor substrate 101 opposite to that of drain electrode 126 (e.g., the first surface of semiconductor substrate 101). For example, epitaxial semiconductor layer 111 can include silicon. Epitaxial semiconductor layer 111 may be a lightly doped layer relative to semiconductor substrate 101. A second surface of semiconductor substrate 101 can be thinned by a thinning process, and drain electrode 126 may be formed on the second surface of semiconductor substrate 101. In some embodiments, a buffer layer may also be provided between semiconductor substrate 101 and epitaxial semiconductor layer 111, and the doping type of the buffer layer can be the same as that of the semiconductor substrate, in order to reduce the instability of the interface between semiconductor substrate 101 and epitaxial semiconductor layer 111 due to defects of semiconductor substrate 101.

A trench can extend from the upper surface of epitaxial semiconductor layer 111 into its interior portion, and may end inside epitaxial semiconductor layer 111. An insulating layer and an electrode conductors can be filled in the trench. The insulating layer can include insulating layer 115, insulating layer 118, and gate dielectric layer 119. The electrode conductor can include conductors 116 and 117. For example, insulating layer 115 and conductor 116 can be formed in the lower portion of the trench, insulating layer 115 may be located on lower sidewall surfaces and a bottom surface of the trench, and insulating layer 115 can separate conductor 116 from epitaxial semiconductor layer 111. Insulating layer 118 can be formed on the top portion of conductor 116. Insulating layer 118 may be formed conformally with insulating layer 115. Gate dielectric layer 119 and conductor 117 can be formed in the upper portion of the trench, and gate dielectric layer 119 may be located on upper sidewall surfaces of the trench and separate conductor 117 from epitaxial semiconductor layer 111. Insulating layer 118 may separate conductor 116 and conductor 117. For example, insulating layer 115 may include an oxide or a nitride (e.g., silicon oxide, silicon nitride, etc.), insulating layer 118 may include an oxide (e.g., silicon oxide, etc.), and gate dielectric layer 119 can be an oxide layer formed by a thermal oxygen process. In addition, conductors 116 and 117 may each include polysilicon.

A first barrier layer can be located on the electrode conductor and the semiconductor base (e.g., epitaxial semiconductor layer 111). The first barrier layer can include interlayer dielectric layer 120 at least partially located above the trench and sidewall spacers 123 located on the sidewalls of interlayer dielectric layer 120. For example, interlayer dielectric layer 120 may be located on the electrode conductor. In this example, interlayer dielectric layer 120 can be located on an upper surface of conductor 117. Interlayer dielectric layer 120 can be used as a mask for the subsequent process of forming the body region and the source region, and a width of interlayer dielectric layer 120 may be set to match a width used as the mask. In this example, the width of interlayer dielectric layer 120 can be equal to a width of trench 112.

Sidewall spacers 123 can be located on the sidewalls of interlayer dielectric layer 120, a contact hole may be located in the semiconductor base on both sides of the sidewall spacers 123, and sidewall spacers 123 may be used as a mask for forming the contact hole. In this example, the contact hole may form a trapezoidal shape with a small bottom and a large top due to the etching process. However, the shape of the contact hole is not limited to this, and may also be a shape of equal width top and bottom, as long as the subsequent source electrode and body contact region can be contacted. Oxide layer 113 can be located between sidewall spacers 123 and the semiconductor base, and oxide layer 113 can protect the surface of the semiconductor base from damage during the subsequent ion implantation process. For example, interlayer dielectric layer 120 may be an oxide layer with a certain thickness, such as silicon oxide. Sidewall spacers 123 may be a nitride layer, e.g., silicon nitride.

Body region 121 of the second doping type may be formed in the upper region of epitaxial semiconductor layer 111 adjacent to the trench, where the junction depth of body region 121 does not exceed the depth of conductor 117 in the trench. Source region 122 of the first doping type can be formed in body region 121. Body contact region 124 of the second doping type may be formed in body region 121, the doping concentration of body contact region 124 is greater than the doping concentration of body region 121 to reduce subsequent ohmic contact resistance with the source electrode. Here, the second doping type is opposite to the first doping type, where the first doping type is one of N-type and P-type, and the second doping type is the other one of N-type and P-type. After body contact region 124 is formed, the source electrode 125 may be formed above interlayer dielectric layer 120 to connect to body contact region 124 and source region 122 via the contact hole. For example, source electrode 125 can be in contact with the upper surface of interlayer dielectric layer 120 and sidewall spacers 123, outer sidewall surfaces of sidewall spacers 123, source region 122, and body contact region 124.

In particular embodiments, a method of making a trench MOSFET can include: forming a trench extending from an upper surface of a semiconductor base to internal portion of the semiconductor base; forming an insulating layer and an electrode conductor in the trench; forming a patterned first barrier layer on an upper surface of the electrode conductor and an upper surface of the semiconductor base; etching part of the semiconductor base to form a contact hole using the patterned first barrier layer as a mask; and forming a body contact region in the semiconductor base through the contact hole using a self-aligned process, where the semiconductor base is of the first doping type, the body contact region is of the second doping type.

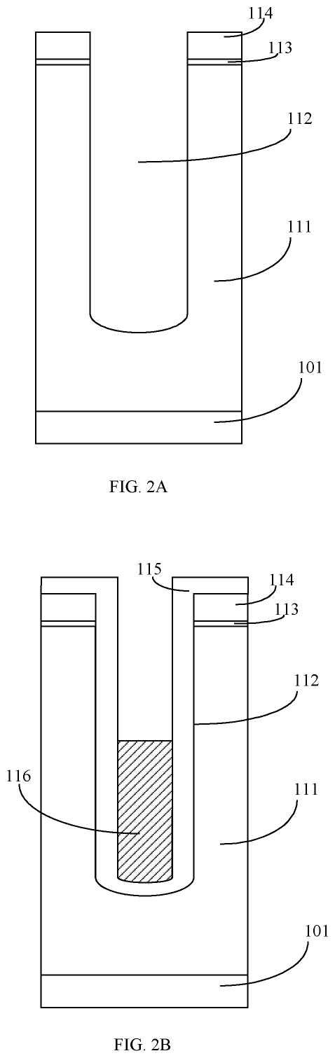

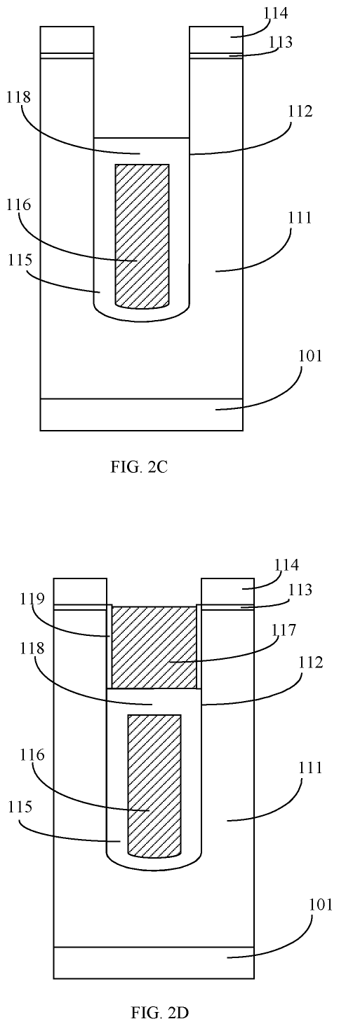

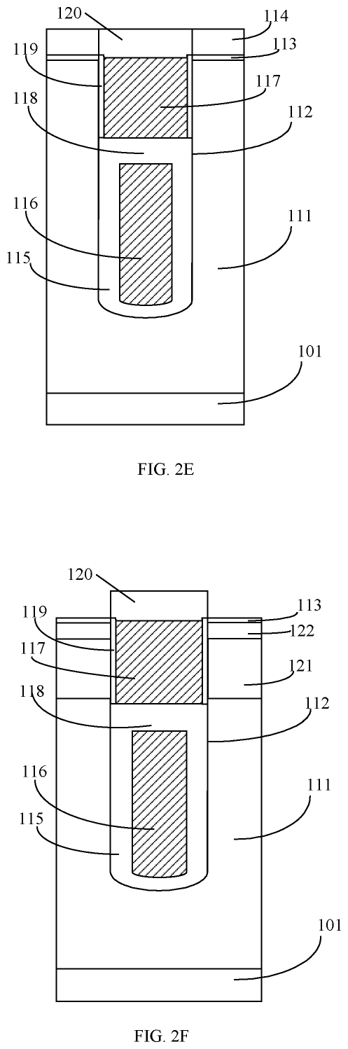

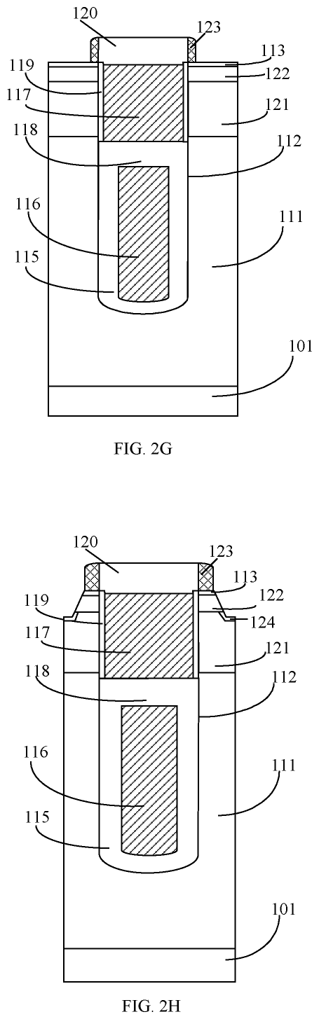

Referring now to FIGS. 2A-2H, shown are cross-sectional view of formation steps of an example method of making a trench MOSFET, in accordance with embodiments of the present invention. In FIG. 2A, trench 112 may extend from an upper surface of the semiconductor base into internal portion of the semiconductor base. For example, the semiconductor base can include semiconductor substrate 101, and epitaxial semiconductor layer 111 located on semiconductor substrate 101. Patterned barrier layer 114 can be formed on epitaxial semiconductor layer 111. Epitaxial semiconductor layer 111 may be etched using patterned barrier layer 114 as a mask, and trench 112 can further be formed in epitaxial semiconductor layer 111. The trench may extend from the upper surface of epitaxial semiconductor layer 111 into the internal portion of epitaxial semiconductor layer 111. For example, the depth of the trench can be controlled by controlling the etching time. In this embodiment, before the step of forming patterned barrier layer 114, the method can include forming oxide layer 113 on epitaxial semiconductor layer 111. In the subsequent ion implantation process, oxide layer 113 can protect the upper surface of epitaxial semiconductor layer 111. For example, patterned barrier layer 114 may be a nitride layer (e.g., silicon nitride). Oxide layer 113 may be formed by a thermal oxidation process. Barrier layer 114 may be formed by a deposition process. Subsequently, an insulating layer and an electrode conductor can be formed in the trench.

As shown in FIG. 2B, insulating layer 115 may be formed along the internal surface of the trench and the upper surface of epitaxial semiconductor layer 101, such as by a thermal oxidation process or chemical vapor deposition (CVD) process. That is, insulating layer 115 may cover a bottom surface and sidewall surfaces of the trench and an upper surface of patterned barrier layer 114. Insulating layer 115 can include of oxide or nitride (e.g., silicon oxide, silicon nitride, etc.). A first conductor may be formed to fill up the trench and to cover the upper surface of patterned barrier layer 114, such as by a low pressure chemical vapor deposition process. Insulating layer 115 may separate the first conductor from epitaxial semiconductor layer 111. Then, the first conductor may be polished by a chemical mechanical polishing process (CMP), and the first conductor can be selectively etched back relative to insulating layer 115 such that the first conductor on the upper surface of patterned barrier layer 114 and occupying an upper portion of the trench may be removed. The remaining first conductor part can be conductor 116 shown in FIG. 2B. The etching back can be performed by a dry etching process, and conductor 116 can include polysilicon.

As shown in FIG. 2C, insulating layer 118 can be formed on the top portion of conductor 116 and insulating layer 115. Insulating layers 115 and 118 may form a conformal shape. Insulating layer 118 can include an oxide (e.g., silicon oxide, etc.). For example, insulating layer 118 may be formed to occupy an upper portion of the trench and cover the upper surface of patterned barrier layer 114. Insulating layers 118 and 115 can be polished by chemical mechanical polishing process to remove insulating layers 118 and 115 covering patterned barrier layer 114. Then, insulating layers 115 and 118 occupying the upper portion of the trench may be further etched back to retain insulating layers 115 and 118 located on conductor 116 and having a certain thickness.

As shown in FIG. 2D, an oxide layer (e.g., gate dielectric layer 119) can be formed on sidewall surfaces of the upper portion of the trench and the first surface of epitaxial semiconductor layer 111, e.g., by a thermal oxidation process, such that the sidewall surfaces of the trench are covered by gate dielectric layer 119. The thermal oxidation process may generally be used to react silicon with gases containing oxides, such as water vapor and oxygen, at high temperatures, and to produce a dense layer of silicon dioxide (SiO2) film on the surface of the silicon wafer, which is an important process of the silicon planar technology.

Further, a second conductor (e.g., gate conductor 117) can fill up the trench covered with gate dielectric layer 119, such as by a low pressure chemical vapor deposition process. For example, the second conductor can include a first portion located inside the trench and a second portion located on the upper surface of patterned barrier layer 114. Then, the second portion of the second conductor on the upper surface of patterned barrier layer 114 may be removed by etching back or chemical mechanical planarization process, such that the second conductor is located inside the trench and the top surface of the second conductor is not higher than the opening of the trench. Alternatively, the conductor layer of gate conductor 117 may be selectively removed relative to patterned barrier layer 114, and the conductor layer can be etched back such that the top surface of conductor 117 is not higher than the upper surface of the epitaxial semiconductor layer. Insulating layer 118 may insulate conductor 116 and conductor 117, and insulating layer 118 may have a specific quality and thickness to support a potential difference that could exist between conductors 116 and 117. For example, the thickness range of insulating layer 118 may be selected 800Å-1500Å, and conductor 117 may include polysilicon.

The insulating layer filled in the trench can include insulating layer 115, insulating layer 118, and gate dielectric layer 119. The electrode conductor filled in the trench can include conductors 116 and 117. It should be noted that the method of filling the insulating layer and the electrode conductor in the trench is not limited to the method disclosed in this application, and those skilled in the art will recognize that other methods to form the second insulating layer can be employed in certain embodiments.

As shown in FIG. 2E, interlayer dielectric layer 120 can be formed on conductor 117. Interlayer dielectric layer 120 may be located between patterned barrier layers 114. In this embodiment, a width of interlayer dielectric layer 120 may be equal to a width of trench 112. For example, a dielectric layer can be formed on conductor 117 and patterned barrier layer 114. A part of the dielectric layer can be removed by chemical mechanical planarization process to obtain a flat surface, such that an upper surface of the dielectric layer and an upper surface of patterned barrier layer 114 is flush to form interlayer dielectric layer 120. For example, interlayer dielectric layer 120 may include an oxide layer (e.g., silicon oxide). Interlayer dielectric layer 120 may be formed by a deposition process. Of course, those skilled in the art will recognize that other methods to remove part of the dielectric layer to obtain a flat surface can be employed in certain embodiments. Finally, patterned barrier layer 114 may be removed by etching process.

As shown in FIG. 2F, using interlayer dielectric layer 120 as a mask, a first ion implantation and driving technique may be performed to form body region 121 of a second doping type in the upper region of epitaxial semiconductor layer 111 adjacent to the trench. Body region 121 may extend from the upper surface of epitaxial semiconductor layer 111 to the inside thereof. Further, using interlayer dielectric layer 120 as a mask, a second ion implantation can be performed to form source region 122 of the first doping type in body region 121. Source region 122 may extend from the upper surface of epitaxial semiconductor layer 111 to the inside thereof. For example, a junction depth of source region 122 may be less than a junction depth of body region 121, and the second doping type may be opposite to the first doping type. The desired doping depth and doping concentration can be achieved by controlling the parameters of ion implantation, such as implantation energy and implantation dose, and the junction depth of body region 121 may not exceed the extension depth of conductor 117 in the trench. For example, body region 121 and source region 122 can respectively be adjacent to the trench and are separated by gate dielectric layer 119 and conductor 117. In the process of forming body region 121 and source region 122, oxide layer 113 may be used to protect the upper surface of epitaxial semiconductor layer 111 to prevent it from being damaged during the ion implantation process.

As shown in FIG. 2G, sidewall spacers 123 can be formed on the sidewalls of interlayer dielectric layer 120, and the patterned barrier layer may include interlayer dielectric layer 120 and sidewall spacers 123. For example, a third insulating layer can be deposited on the upper surface and sidewalls of the interlayer dielectric layer and the upper surface of the semiconductor base, and the third insulating layer on the upper surface of the interlayer dielectric layer and part of the upper surface of the semiconductor base are etched to form sidewall spacer 123. For example, the material of sidewall spacer 123 can include a nitride layer (e.g., silicon nitride).

As shown in FIG. 2H, using interlayer dielectric layer 120 and sidewall spacers 123 (e.g., the patterned barrier layer) as a mask, a part of epitaxial semiconductor layer 111 (e.g., source region 122 and body region 121) located outside sidewall spacer 123 can be etched to form a contact hole. A third ion implantation may be performed, and a self-aligned process is adopted to form body contact region 124 in body region 121 through the contact hole. Body contact region 124 may extend from the upper surface of the etched body region to the inside thereof, and body contact region 124 may be of the second doping type. For example, the contact hole can form a trapezoidal shape with a small bottom and a large top due to the etching process.

As shown in FIG. 1, a metal can be deposited on interlayer dielectric layer 120 to form source electrode 125. For example, a metal is deposited on the upper surface of the structure formed in FIG. 2H to form source electrode 125. Source electrode 125 can be in contact with source region 122 and body contact region 124 through the contact hole. Subsequently, by the above-mentioned known deposition process, drain electrode 126 can be formed on the second surface of semiconductor base 101 thinned by the thinning process. In the above example, source electrode 125 and drain electrode 126 may include conductive materials (e.g., aluminum alloy, copper, etc.).

In particular embodiments of the trench MOSFET and the manufacturing method thereof, the barrier layer used when forming the trench can be repeatedly used to form the interlayer dielectric layer of the trench MOSFET, and the interlayer dielectric layer may also be used as a mask in the step of forming the body region and the source region. Then, the barrier layer can be removed, and sidewall spacers may be formed on the sidewalls of the interlayer dielectric layer to serve as a mask in the step of forming the contact hole and the body contact region. In this way, the method of making a trench MOSFET may not only simplify the process, but also solve the problem of the alignment deviation of the gate-source contact, and also improve process consistency.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A method of manufacturing a trench metal-oxide-semiconductor field-effect transistor (MOSFET), the method comprising:
a) forming a trench extending from an upper surface of a semiconductor base to internal portion of the semiconductor base;
b) forming an insulating layer and an electrode conductor in the trench;
c) forming a patterned first barrier layer on an upper surface of the electrode conductor and an upper surface of the semiconductor base;
d) etching part of the semiconductor base to form a contact hole using the patterned first barrier layer as a mask; and
e) forming a body contact region in the semiconductor base through the contact hole using a self-aligned process, wherein the semiconductor base is of the first doping type, the body contact region is of the second doping type.

2. The method of claim 1, wherein the forming the patterned first barrier layer comprises:
a) forming an interlayer dielectric layer on the electrode conductor; and
b) forming sidewall spacers on the sidewalls of the interlayer dielectric layer to form the patterned first barrier layer.

3. The method of claim 2, wherein before the forming the contact hole, further comprises forming a body region and a source region in the upper region of the semiconductor base adjacent to the trench.

4. The method of claim 3, wherein the forming the body region and the source region comprises:
a) using the interlayer dielectric layer as a mask to form the body region; and
b) using the interlayer dielectric layer as a mask to form the source region in the body region, wherein the body region is of the second doping type, the source region is of a first doping type, the first doping type is opposite to the second doping type, and the body contact region is located in the body region.

5. The method of claim 2, wherein the forming the trench comprises:
a) forming a patterned second barrier layer on the upper surface of the semiconductor base; and
b) etching the semiconductor base to form the trench using the patterned second barrier layer as a mask.

6. The method of claim 5, wherein the forming the interlayer dielectric layer comprises:
a) forming a dielectric layer on the electrode conductor and the patterned second barrier layer;
b) planarizing the dielectric layer to make the dielectric layer be flush with the upper surface of the patterned second barrier layer; and
c) removing the patterned second barrier layer.

7. The method of claim 1, wherein the forming the insulating layer and the electrode conductor comprises:
a) forming a first insulating layer and a first conductor occupying a lower portion of the trench, wherein the first insulating layer is located on a lower sidewall surface and a bottom surface of the trench and separates the first conductor from the semiconductor base;
b) forming a second insulating layer covering a top portion of the first conductor;
c) forming a gate dielectric layer and a second conductor occupying an upper portion of the trench, wherein the gate dielectric layer is located on an upper sidewall surface of the trench and separates the second conductor from the semiconductor base; and
d) wherein the insulating layer comprises the first insulating layer, the second insulating layer, and the gate dielectric layer, and the electrode conductor comprises the first conductor and the second conductor.

8. The method of claim 5, wherein the patterned second barrier layer is formed by a deposition process, and the patterned second barrier layer comprises a nitride layer.

9. The method of claim 2, wherein the forming the sidewall spacers on the sidewalls of the interlayer dielectric layer comprises:
a) depositing a third insulating layer on an upper surface and sidewalls of the interlayer dielectric layer, and on the upper surface of the semiconductor base; and
b) etching the third insulating layer on the upper surface of the interlayer dielectric layer and the upper surface of the semiconductor base to form the sidewall spacers.

10. The method of claim 2, wherein the sidewall spacers comprise a nitride layer.

11. The method of claim 2, further comprising:
a) forming a source electrode by depositing metal on the interlayer dielectric layer and the semiconductor base, the source electrode being in contact with the body contact region through the contact hole; and
b) forming a drain electrode by depositing metal on a back surface of the semiconductor base.

12. A trench metal-oxide-semiconductor field-effect transistor (MOSFET), comprising:
a) a semiconductor base having a first doping type;
b) a trench extending from an upper surface of the semiconductor base to internal portion of the semiconductor base;
c) an insulating layer and an electrode conductor located in the trench;
d) a body region having a second doping type and extending from the upper surface of the semiconductor base to the inside thereof and adjacent to the trench;
e) a source region having the first doping type and located in the body region;
f) a first barrier layer located on the electrode conductor and the semiconductor base; and
g) a contact hole in the semiconductor base on both sides of the first barrier layer, wherein the contact hole is formed by etching process using the first barrier layer as a mask.

13. The trench MOSFET of claim 12, wherein the first barrier layer comprises an interlayer dielectric layer at least partially located above the trench and sidewall spacers located on sidewalls of the interlayer dielectric layer.

14. The trench MOSFET of claim 13, wherein the body region and the source region are formed using the interlayer dielectric layer as a mask.

15. The trench MOSFET of claim 14, wherein a width of the interlayer dielectric layer is set to match the mask used as the body region and the source region.

16. The trench MOSFET of claim 12, wherein a width of a bottom part of the contact hole is less than that of a top part of the contact hole.

17. The trench MOSFET of claim 12, further comprising a body contact region of the second doping type in the body region.

18. The trench MOSFET of claim 12, wherein:
a) the insulating layer in the trench comprises a first insulating layer, a second insulating layer, and a gate dielectric layer;
b) the first insulating layer covers a lower sidewall surface and a bottom surface of the trench;
c) the gate dielectric layer covers an upper surface of the trench;
d) a second insulating layer is located between the first insulating layer and the gate dielectric layer; and
e) the thickness of the first insulating layer is greater than the thickness of the gate dielectric layer.

19. The trench MOSFET of claim 18, wherein:
a) the electrode conductor in the trench comprises a first conductor located in the lower part of the trench and a second conductor located in the upper part of the trench;
b) the first insulating layer separates the first conductor from the semiconductor base, the gate dielectric layer separates the second conductor from the semiconductor base; and
c) the second insulating layer separates the first conductor from the second conductor.

20. The trench MOSFET of claim 17, further comprising:
a) a source electrode located on the interlayer dielectric layer, wherein the source electrode is in contact with the body contact region and the source region through the contact hole; and
b) a drain electrode located on the back surface of the semiconductor base.
